(19) United States
(12) Patent Application Publication
(10) Pub. No.: US 2014/0003122 A1
(43) Pub. Date: Jan. 2, 2014

(54) SEMICONDUCTOR MEMORY STRUCTURE AND CONTROL METHOD THEREOF

(71) Applicants: Pengfei Wang, Shanghai (CN); Qingqing Sun, Shanghai (CN); Wei Zhang, Shanghai (CN)

(72) Inventors: Pengfei Wang, Shanghai (CN); Qingqing Sun, Shanghai (CN); Wei Zhang, Shanghai (CN)

(73) Assignee: Fudan University, Shanghai (CN)

(21) Appl. No.: 13/501,833

(22) PCT Filed: Aug. 15, 2011
(86) PCT No.: PCT/CN2011/001353

§ 371 Date: Apr. 13, 2012

(30) Foreign Application Priority Data
May 10, 2011 (CN) 20110119859.0

(51) Int. Cl. G11C 13/00

(52) U.S. Cl. CPC G11C 13/0002
USPC 365/148

(57) ABSTRACT

The present invention belongs to the technical field of non-volatile semiconductor memories, and relates to a semiconductor memory structure and a control method thereof. The semiconductor memory structure in the present invention comprises a memory unit for storing information and a tunneling field-effect transistor connected with the memory unit. The tunneling field-effect transistor is used for controlling the semiconductor memory's operations such as erasing, writing, and reading. A plurality of semiconductor memory structures compose a semiconductor memory array. The control method provided by the present invention comprises steps of resetting, setting, and reading. A vertical gate-controlled diode structure in a tunneling field-effect transistor is capable of providing a large current for writing a resistive random access memory and a phase change memory and improving the density of the memory array and therefore is very suitable for use in manufacturing of semiconductor memory chips; besides, the control method and the control circuit thereof are simple.

### BACKGROUND OF THE INVENTION

1. Technical Field

The present invention belongs to the technical field of non-volatile semiconductor memories and relates to a semiconductor memory and a control method thereof, in particular to a semiconductor memory adopting a self-aligned process and a control method thereof.

2. Description of Related Art

As with the development of microelectronic technology, the development of integrated circuit chips basically follows Moore's law, which means the integrated degree of semiconductor chips is doubled every 18 months. This makes the design of integrated circuits turn in the direction of system-on-chip (SOC) integration, and the key technology to realize SOC is the integration of memory-on-chip with low power consumption, high density, and high access speed. By means of the current technology, integrated circuit devices are about 30 nm; however, limited by high coupling ratios, high voltage, etc., traditional Flash floating gate memory is difficult to reduce to below 30 nm, so the development of non-volatile memory has become a current research hotspot. Both phase change memories and resistive random access memories can be used as new memories.

Phase change memory stores data by means of the huge conductive difference of the sulfur compounds between the crystalline state and the non-crystalline state. The phase change is an invertible phenomenon occurring when the sulfur compounds are turned from the amorphous phase to the crystalline phase. In the amorphous phase, the materials are in a highly orderless state and have no crystal grids. In this state, the materials have high impedance and high reflectivity. Oppositely, in the crystalline phase, the materials have a regular crystal structure, low impedance, and low reflectivity. Phase change memory uses the impedance difference between the two phases. The huge amount of heat generated by current injection is capable of triggering the phase change of the materials. The properties of the materials after phase change are determined according to the injected current, the voltage, and the operating time. FIG. 1 illustrates a sectional view of a typical phase change memory unit. As shown in FIG. 1, a sulfur compound layer 100 is included between a top electrode 105 and a bottom electrode 101, and a heating resistor 102 extending from the bottom electrode 101 contacts the sulfur compound layer 100. The joule heat generated by injecting an electric current into the connection point of the heating resistor 102 and the sulfur compound layer 100, a region 103 at the amorphous phase, is generated in the sulfur compound layer 100 with a crystal structure, a region 104 is of crystalline phase, and due to the difference in the reflectivity, the region 103 at the amorphous phase is mushroom-shaped. FIG. 1 illustrates a general equivalent circuit diagram of a phase change memory unit. As shown in FIG. 2, the phase change memory unit 106 comprises a transistor 107 and a phase change element 108, a source electrode/drain electrode (S/D) of the transistor 107 is grounded, while the other S/D of the transistor 107 is connected with one end of the phase change element 108. A gate electrode of the transistor 107 is connected with a gate voltage V_{G}. The other end of the phase change element 108 is connected with a bit line voltage V_{BL}. When accessing the data stored in the memory unit 108, the voltage V_{G} is applied to the transistor 107 which is started, the bit line voltage V_{BL} is applied to the phase change element 108, so “a” 11 applies a voltage onto the transistor 107 and opens the transistor 107, and the bit line 108 applies a voltage to the memory 108 to make an accessed current pass through the phase change element 108 and the transistor 107. Based on the output current, the data stored in the phase change unit 120 is capable of being accessed. Compared with traditional Flash floating gate memory, the phase change memory has higher writing and erasing speeds and a better scalability.

The information reading and writing of the resistive random access memory is realized by reading or changing the resistance of the resistive switching materials. FIG. 3 illustrates a basic structural view of a resistive random access memory. As shown in FIG. 3, a resistive switching storage layer 110 is arranged between an upper electrode 109 and a lower electrode 111. The upper electrode 109 and the lower electrode 111 are usually made of metal materials such as Pt and Ti with stable chemical properties, and the resistive switching storage layer 110 is usually made from binary or ternary metallic oxides such as TiO₂, ZrO, Cu₂O and SrTiO₃. The resistance of the resistive switching storage layer 110 is capable of being switched between two states, namely a high impedance state and low impedance state, which can be represented by “0” and “1” respectively, by the action of external voltages. By the effect of different external voltages, the resistance of the resistive random access memory is capable of being invertibly switched between the high impedance state and the low impedance state, to conduct the information storage function. In the reading and writing operations of the resistive random access memory, generally the high impedance state is defined to store 0 which is a binary-system element and the low impedance state is defined to store 1 which is a binary-system element. The original impedance state of the resistive switching material is high impedance state, so the operation (the corresponding resistive switching material is turned from the high impedance state into the low impedance state) of writing 1 into the information bit is defined as a writing operation, and the operation (the corresponding resistive switching material is turned from the low impedance state into the high impedance state) of writing 0 into the information bit is defined as the erasing operation. The writing operation of a device generally requires applying a short voltage impulse of about 1-5V between the top electrode and the bottom electrode and setting a proper maximal current limit to avoid device failure caused by sudden increase of current by several magnitudes in the process where the resistive switching material is turned from the high impedance state to the low impedance state. The erasing operation of the device generally requires applying a short voltage impulse of about 0.5-1V towards the same or opposite direction of the writing voltage. The voltage impulse width for writing and erasing ranges from tens of nanoseconds to hundreds of microseconds and is determined according to the specific properties of the resistive switching material. The width of the erasing voltage is generally bigger than that of the writing impulse. The reading of the information stored in the device is capable of being realized by applying a small voltage of about 0.2V and detecting the corresponding current. The resistivity of the materials is unrelated to the dimensions of the materials; so theoretically, the storage performance of resistive random access memory does not decline with the shrinkage of the device's dimensions. This determines that the potential integration capability of resistive random access memory is far higher than that of the current major Flash floating gate memories. Besides, resistive random access memory is simple in structure and is capable of realizing integration with the existing CMOS production process easily.

However, both the phase change memory and the resistive random access memory need a large erasing current, so they shall be erased by a special array access device.

### BRIEF SUMMARY OF THE INVENTION

The present invention aims to provide a semiconductor memory device, which can realize the operations of reading and writing semiconductor memory with a special array access device.

To fulfill the mentioned aim, the present invention provides a semiconductor memory structure. The semiconductor memory structure comprises a resistive switching memory unit and a tunneling field-effect transistor for operating the semiconductor memory, wherein the tunneling field-effect transistor comprises a source electrode, a drain electrode, a low-doped channel region, and a gate electrode; the gate electrode of the tunneling field-effect transistor is connected with any one of a plurality of word lines, while the source electrode is connected with any one of a plurality of source lines, and the two ends of a variable resistor thereof are respectively connected to the bit line and the drain electrode of the tunneling field-effect transistor.

A method for controlling the semiconductor memory structure comprises the steps of resetting, setting and reading.

The step of resetting the semiconductor memory structure is to: apply a first voltage to the source line which is connected with the semiconductor memory structure, apply a second voltage to the word line which is connected with the semiconductor memory structure, and apply a third voltage to the bit line which is connected with the semiconductor memory structure, to make the p-n node diode of the tunneling field-effect transistor in the semiconductor memory structure positively polarized, so the semiconductor memory structure is reset and the resistance thereof is increased.

Furthermore, the first voltage ranges from 0.1V to 4V, the second ranges from −1V to 1V, and the third from 0V to 3V.

The step of setting the semiconductor memory structure is to: apply a fourth voltage to the source line which is connected with the semiconductor memory structure, apply a fifth voltage to the word line which is connected with the semiconductor memory structure, and apply a sixth voltage to the bit line which is connected with the semiconductor memory structure, so the semiconductor memory structure is set and the resistance thereof is reduced.

Furthermore, the fourth voltage ranges from 0V to −3V, the fifth ranges from 0 to 10V, and the sixth from 0.1V to 3V.

The step of reading the semiconductor memory structure is to: apply a seventh voltage to the source line which is connected with the semiconductor memory structure, apply an eighth voltage to the word line which is connected with the semiconductor memory structure, and apply a ninth voltage to the bit line which is connected with the semiconductor memory structure, so the data stored in the semiconductor memory structure is selected and read based on the size of the output current.

Furthermore, the seventh voltage ranges from 0V to −3V, the eighth ranges from 0 to 10V, and the ninth from 0.1V to 2V.

Furthermore, the drain electrode of the tunneling field-effect transistor in the semiconductor memory structure provided by the present invention is positioned at the top of a platform structure which is vertical to a horizontal surface. The platform structure has a semiconductor substrate, the drain electrode is positioned in the substrate which is positioned at the bottom of the platform structure and extends outwards, the low-doped channel region is positioned between the drain electrode and the source electrode, and the gate electrode covers the part below the low-doped region of the platform structure to control the current passing through the source electrode and the drain electrode of the channel region. The semiconductor substrate may be single crystal silicon, polycrystalline silicon or silicon (SOI) on an insulator. The gate electrode is a laminated structure, comprising at least one conductive layer and an insulation layer which isolates the conductive layer from the semiconductor substrate, wherein the conductive layer may be polycrystalline silicon, amorphous silicon, metal tungsten, titanium nitride, tantalum nitride or metallic silicon compound; and the insulation layer may be one or mixture of several of SiO₂, HfO₂, HfSiO, HfSiON, SiON and Al₂O₃.

The conductive layer of the gate electrode surrounds the periphery of the vertical low-doped channel region to form a sidewall structure, and the resistive switching memory unit is made from a phase change material or a resistive switching material.

The device structure provided by the present invention is also capable of forming a semiconductor memory array. A method for controlling the semiconductor memory array comprises resetting a plurality of memories in the semiconductor memory array and then setting individual memories.

According to the method for controlling the semiconductor memory structure, the tunneling field-effect transistor is adopted to carry out operations such as erasing, writing, and reading the semiconductor memory structure, the vertical gate-controlled diode structure in the tunneling field-effect transistor is capable of providing a large current for writing the resistive random access memory and the phase change memory and improving the density of the memory array and therefore is very suitable for use in manufacturing semiconductor memory chips; besides, the control method and the control circuit are simple.

### BRIEF DESCRIPTION OF THE SEVERAL VIEWS OF THE DRAWING

FIG. 1 is a sectional view of a typical resistive random access memory unit.

FIG. 2 is a general equivalent circuit diagram of a typical resistive random access memory unit.

FIG. 3 is a sectional view of a typical resistive random access memory unit.

FIG. 4 is a top view of one embodiment of a semiconductor memory structure provided by the present invention.

FIG. 5 is a sectional view of one embodiment of a semiconductor memory structure provided by the present invention.

FIG. 6 is an equivalent circuit diagram of one embodiment of a semiconductor memory structure provided by the present invention.

FIG. 7 is a resetting equivalent circuit diagram of one embodiment of a method for controlling a semiconductor memory structure provided by the present invention.

FIG. 8 is a setting equivalent circuit diagram of one embodiment of a method for controlling a semiconductor memory structure provided by the present invention.

FIG. 9 is a reading equivalent circuit diagram of one embodiment of a method for controlling a semiconductor memory structure provided by the present invention.

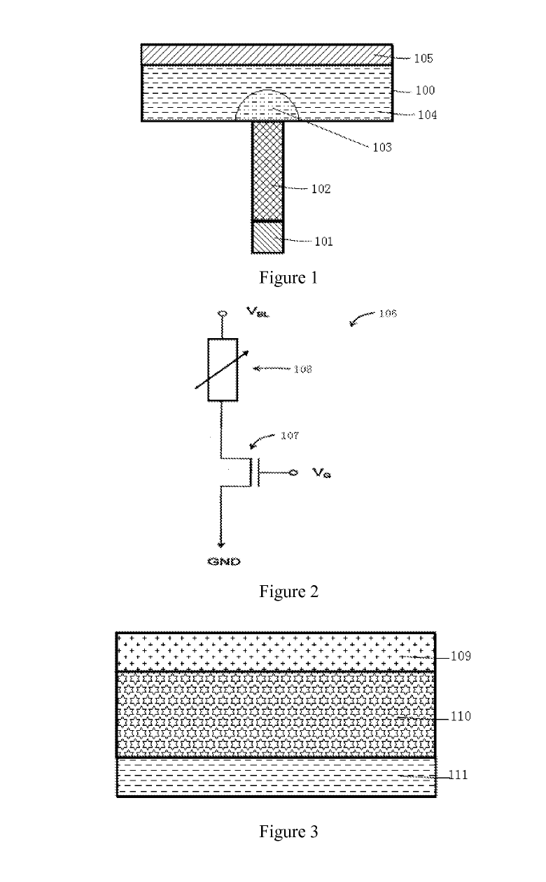

### DETAILED DESCRIPTION OF THE INVENTION

The embodiment of the present invention is further described in detail by means of the attached drawings. In the figure, to facilitate description, the layer thickness and region thickness are amplified, but the sizes do not represent the actual dimensions. The attached drawings are schematic views of an ideal embodiment. The embodiment of the present invention shall not be limited to the specific shapes of the regions as shown in the figure, but shall comprise all shapes, like deviation caused by manufacturing.

For example, an etched curve is usually characterized in bends or roundness and smoothness. But in this embodiment, all curves are represented by rectangles. The figure is schematic and shall not be considered as a limit of the present invention. Meanwhile, in the below description, the term “wafer” and “substrate” may be considered to comprise a semiconductor wafer being processed or other films prepared on the semiconductor wafer.

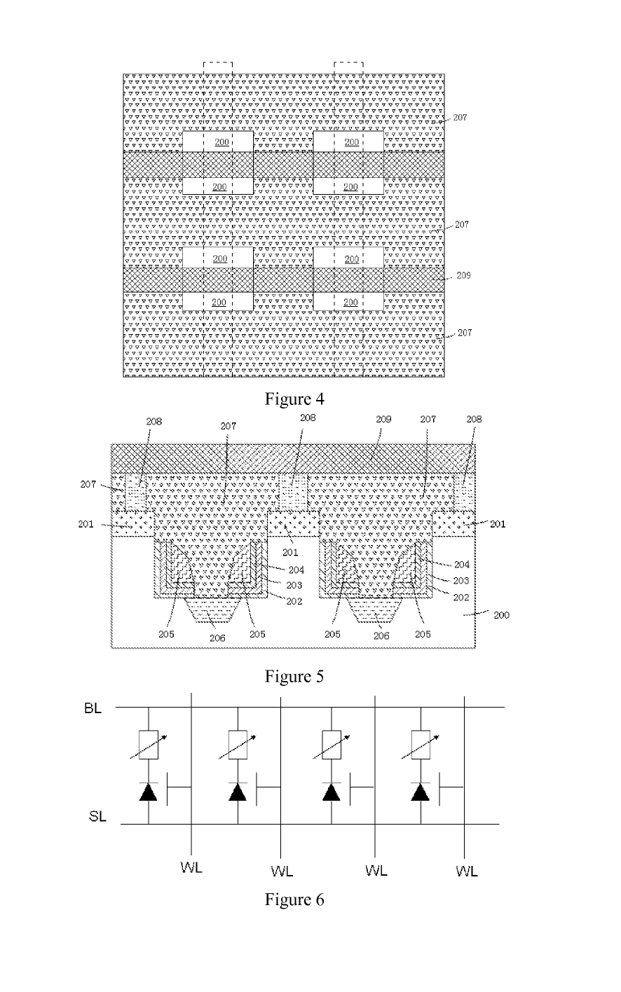

FIG. 4 is a top view of a method for controlling the semiconductor memory structure provided by the prevent invention. As shown in FIG. 4 and FIG. 5, 200 represents the semiconductor substrate; 201 represents an n-type ion-doped region; 202 represents a SiO₂ gate dielectric; 203 represents a gate dielectric with a high k material; 204 represents a conductive gate layer such as TiN or TaN, and the conductive gate layer 204 surrounds the periphery of a vertical channel to form a sidewall structure; 205 represents polycrystalline silicon; 202, 203, 204 and 205 as shown in the figure form the gate electrode of a tunneling field-effect transistor, and the channel of the gate cover is vertical to the substrate surface at the tunneling field-effect transistor; 206 represents a p-type ion-doped region; 208 represents an insulation layer formed by insulating materials such as SiO2, Si3N4 or a mixture of the two; 208 represents a memory unit which is formed by a phase change material or a resistive switching material and used for storing charges; and 209 represents a metal electrode which is connected with the memory unit 208 and may be made from TiN, Ti, Ta or TaN. The gate electrode of the tunneling field-effect transistor can control the current passing through the memory unit 208 to realize the operations of reading and writing the memory unit 208.

FIG. 6 is an equivalent circuit diagram of a method for controlling a semiconductor memory structure provided by the present invention. As shown in FIG. 6, the bit line BL is connected with the metal electrode 209, the word line WL is connected with the gate electrode of the tunneling field-effect transistor, and the source line SL is connected with the source electrode or drain electrode of the tunneling field-effect transistor.

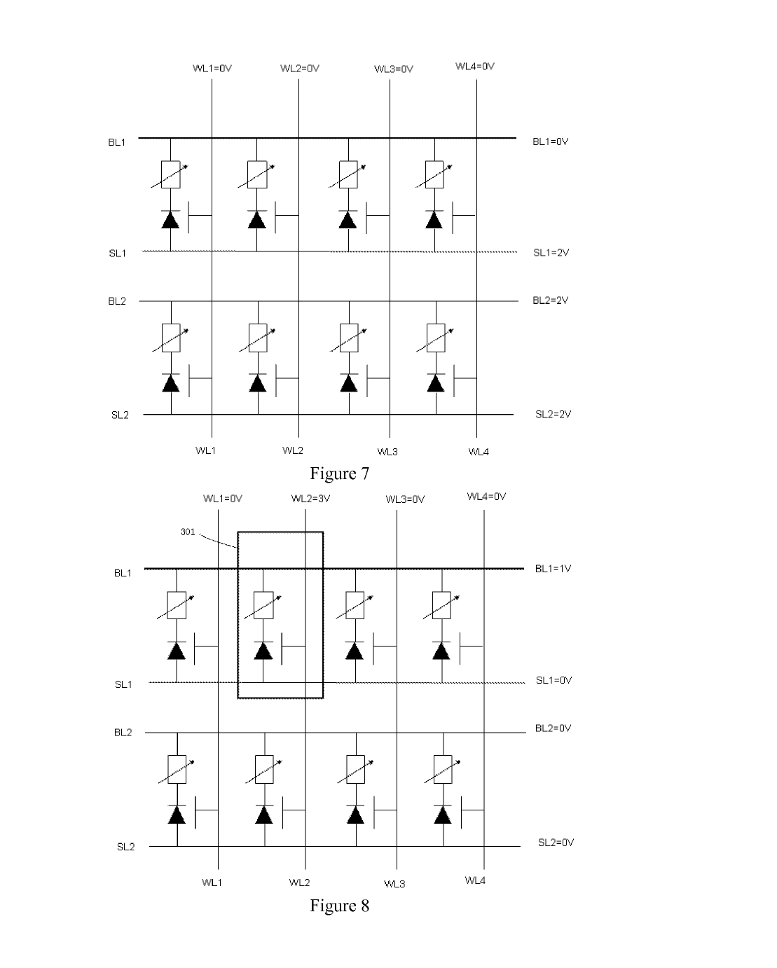

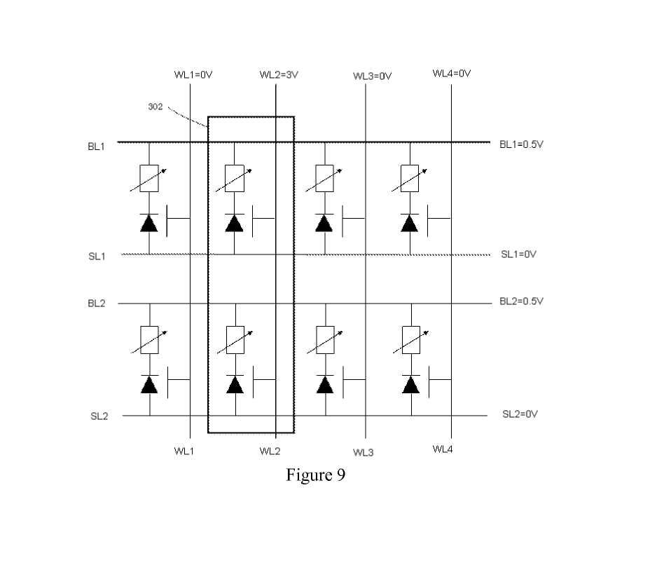

A plurality of semiconductor memories as shown in FIG. 5 can compose a semiconductor memory array. FIG. 7, FIG. 8 and FIG. 9 respectively are equivalent circuit diagrams for resetting, setting and reading a semiconductor memory array.

Specifically, as shown in FIG. 7, the step for resetting the semiconductor memory array is as follows:

Apply a voltage of 2V to both the sources lines SL1 and SL2;

Apply a voltage of 0V to all word lines WL1, WL2, WL3 and WL4;

Apply a voltage of 0V to the bit line BL1 and a voltage of 2V to the bit line BL2;

wherein due to SL2=BL2=2V, the memory connected with BL2 has no current; due to BL1=0V<L1=0V, the p-n node of the tunneling field-effect transistor connected with BL1 is positively polarized and has a passing current, so the memory connected with BL1 is selected and the reset and the resistance thereof is increased.

Specifically, as shown in FIG. 8, the step for setting the semiconductor memory array is as follows:

Apply a voltage of 0V to both sources lines SL1 and SL2;

Apply a voltage of 0V to all word lines WL1, WL3 and WL4 and a voltage of 3V to the word line WL2;

Apply a voltage of 1V to the bit line BL1 and a voltage of 0V to the bit line BL2;

wherein due to WL2=3V>SL1=0V, the p-n node of the tunneling field-effect transistor represented by 301 in FIG. 8 is reversely polarized, so the memory device in 301 is selected and set and the resistance thereof is reduced.

Specifically, as shown in FIG. 9, the step for reading the semiconductor memory array is as follows:

Apply a voltage of 0V to both sources lines SL1 and SL2;

Apply a voltage of 0V to all word lines WL1, WL3 and WL4 and a voltage of 3V to the word line WL2;

Apply a voltage of 0.5V to the bit lines BL1 and BL2.

Based on the output current, the data stored in the memory unit represented by 302 in FIG. 9 is capable of being read. To prevent the setting operation, the voltage applied to the bit lines BL in the reading step is lower that applied to the bit lines BL in the setting step.

### INDUSTRIAL APPLICATION

According to the invention, the vertical gate-controlled diode structure in the tunneling field-effect transistor is capable of providing a large current for writing the resistive random access memory and the phase change memory and improving the density of the memory array and therefore is very suitable for use in manufacturing semiconductor memory chips; besides, the control method and the control circuit are simple.

As mentioned above, a plurality of embodiments with great differences may be constructed. It should be noted that, except those defined in the attached claims, the present invention is not limited to the embodiments in the description.

1. A semiconductor memory structure comprises a resistive switching memory unit and a tunneling field-effect transistor for operating the semiconductor memory,
wherein the tunneling field-effect transistor comprises a source electrode, a drain electrode, a low-doped channel region, and a gate electrode;
the gate electrode of the tunneling field-effect transistor is connected with any one of a plurality of word lines, while the source electrode is connected with any one of a plurality of source lines, and the two ends of a variable resistor thereof are respectively connected to the bit line and the drain electrode of the tunneling field-effect transistor.

2. The semiconductor memory structure of claim 1, wherein the drain electrode of the tunneling field-effect transistor in the semiconductor memory structure is positioned at the top of a platform structure which is vertical to a horizontal surface, and the platform structure has a semiconductor substrate; the drain electrode is positioned in the substrate which is positioned at the bottom of the platform structure and extends outwards; the low-doped channel region is positioned between the drain electrode and the source electrode, and the gate electrode covers the part below the low-doped region of the platform structure to control the current passing through the source electrode and the drain electrode of the channel region.

3. The semiconductor memory structure of claim 1, wherein the semiconductor substrate may be single crystal silicon, polycrystalline silicon or silicon on an insulator (SOI); the gate electrode is a laminated structure, comprising at least one conductive layer and an insulation layer which isolates the conductive layer from the semiconductor substrate, wherein the conductive layer may be polycrystalline silicon, amorphous silicon, metal tungsten, titanium nitride, tantalum nitride or metallic silicon compound; and the insulation layer may be one or mixture of several of SiO₂, HfO₂, HfSiO, HfSiON, SiON and Al₂O₃.

4. The semiconductor memory structure of claim 1, wherein the conductive layer of the gate electrode surrounds the periphery of the vertical low-doped channel region to form a sidewall structure, and the resistive switching memory unit is made from a phase change material or a resistive switching material.

5. The method for controlling the semiconductor memory structure of claim 1 comprises the steps of resetting, setting and reading;
the step of resetting the semiconductor memory structure is to:
apply a first voltage to the source line which is connected with the semiconductor memory structure,
apply a second voltage to the word line which is connected with the semiconductor memory structure,
and apply a third voltage to the bit line which is connected with the semiconductor memory structure,
to make the p-n node diode of the tunneling field-effect transistor in the semiconductor memory structure positively polarized, so the semiconductor memory structure is reset and the resistance thereof is increased;
the step of setting the semiconductor memory structure is to:
apply a fourth voltage to the source line which is connected with the semiconductor memory structure,
apply a fifth voltage to the word line which is connected with the semiconductor memory structure,
and apply a sixth voltage to the bit line which is connected with the semiconductor memory structure,
so the semiconductor memory structure is set and the resistance thereof is reduced;
the step of reading the semiconductor memory structure is to:
apply a seventh voltage to the source line which is connected with the semiconductor memory structure,
apply an eighth voltage to the word line which is connected with the semiconductor memory structure,
and apply a ninth voltage to the bit line which is connected with the semiconductor memory structure,
so the data stored in the semiconductor memory structure is selected and read based on the size of the output current.

6. The method for controlling the semiconductor memory structure of claim 5, wherein the first voltage ranges from 0.1V to 4V, the second voltage ranges from −1V to 1V, and the third voltage from 0V to 3V.

7. The method for controlling the semiconductor memory structure of claim 5, wherein the fourth voltage ranges from 0V to −3V, the fifth ranges from 0 to 10V, and the sixth from 0.1V to 3V.

8. The method for controlling the semiconductor memory structure of claim 5, wherein the seventh voltage ranges from 0V to −3V, the eighth ranges from 0 to 10V, and the ninth from 0.1V to 2V.

9. A semiconductor memory array is constituted of the semiconductor memory structure of claim 1.

10. A method for controlling the semiconductor memory array of claim 9 comprises resetting a plurality of memories in the semiconductor memory array and then setting individual memories.
